(19) United States
(12) Patent Application Publication
(10) Pub. No.: US 2024/0294819 A1
(43) Pub. Date: Sep. 5, 2024

(54) COMPOSITION, LIQUID COOLING AGENT AND APPLICATIONS THEREOF, AND IMMERSION COOLING SYSTEM

(71) Applicant: Zhejiang Juhua Technology Center Co., Ltd, Quzhou City, Zhejiang (CN)

(72) Inventors: Liyang ZHOU, Quzhou City, Zhejiang (CN); Shuhua WANG, Quzhou City, Zhejiang (CN); Guangxin ZHANG, Quzhou City, Zhejiang (CN); Xingping WANG, Quzhou City, Zhejiang (CN); Hao LI, Quzhou City, Zhejiang (CN); Zhigang LEI, Quzhou City, Zhejiang (CN); Wenjun JIANG, Quzhou City, Zhejiang (CN)

(21) Appl. No.: 18/573,787

(22) PCT Filed: Jun. 14, 2022
(86) PCT No.: PCT/CN2022/098632

§ 371 Date: Dec. 22, 2023

(30) Foreign Application Priority Data
Jun. 25, 2021 (CN) 202110711798.0

(51) Int. Cl. C09K 5/10; H05K 7/20

(52) U.S. Cl. CPC C09K 5/10; H05K 7/20772

(57) ABSTRACT

The present disclosure relates to the technical field of liquid cooling media. Disclosed are a composition, a liquid cooling agent and applications thereof, and an immersion cooling system. The composition is a perfluoropolyether compound having a structural general formula A-(R_{CF}O)ₙ—(CF₂O)ₘ—(CF₂)_{z}—B, or a combination of the perfluoropolyether compound and perfluoropolyether diol having a structural general formula HO—CH₂—(CF₂)_{q}—(R_{CF}O)ₙ—(CF₂O)ₘ—(CF₂)_{z}—CH₂OH. Groups (R_{CF}O) and (CF₂O) are randomly distributed. A is a group —F, —CF₃, CF₃CF₂—, CF₃—O—, or CF₃CF₂—O—; B is a group —CF₃ or —CF₂CF₃; R_{CF} is a group —CF₂CF₂—, —CF₂CF₂CF₂—, or —CF(CF₃)CF₂—; z is an integer between 0 and 2; n and m are both integers greater than 0; n+m=2-30; n/m=1-30; q is an integer greater than 0. The present disclosure solves the existing problem of poor compatibility between a component of the liquid cooling agent and an electronic device material. The liquid cooling agent of the present disclosure has good fluidity and excellent heat-dissipation performance, improves the compatibility between the component of the liquid cooling agent and the electronic device material, and protects an electronic device from being damaged.

### CROSS-REFERENCE TO RELATED APPLICATIONS

The application is a U.S. National Stage Application of Patent Application No. PCT/CN2022/098632 filed Jun. 14, 2022, which claims the benefits of the Chinese Application No. 202110711798.0, filed on Jun. 25, 2021, entitled “COMPOSITION, LIQUID COOLING AGENT, APPLICATIONS OF LIQUID COOLING AGENT, AND IMMERSION COOLING SYSTEM”, the contents of each application being are specifically and entirely incorporated herein by reference.

### FIELD

The present disclosure relates to the technical field of liquid cooling media, in particular to a composition, a liquid cooling agent and application thereof, and an immersion cooling system.

### BACKGROUND

Due to the upgrading and development of science and technology industries such as high-performance computers, data center servers, and new energy automobiles, the problem of equipment energy consumption is increasingly prominent. The computer equipment and power batteries tend to generate a large amount of heat during operation so the operation efficiency is reduced, if the problem of reduced operation efficiency cannot be effectively processed, the operation of the computer equipment and the power batteries will be necessarily influenced. At present, the electric energy consumption of the data center is mainly concentrated on servers running all year round and the attached heat dissipation equipment. If the equipment adopts an effective heat dissipation mode, it can transform the heat and sharply reduce the electric energy consumption. The heat dissipation equipment has two arrangement modes, one mode is the commonly used air cooling heat dissipation system, but the energy efficiency of the air cooling system is lower, thus the energy consumption of the heat dissipation equipment stays at a high level; the other mode is a liquid cooling heat dissipation system, which can be divided into an indirect contact type liquid cooling and a direct immersion type liquid cooling. The direct immersion type liquid cooling relates to directly immersing a heat generation element in a non-conductive cooling liquid for absorbing heat and taking away the heat generated from the operation of the equipment (e.g., a server) by means of flow and circulation of the liquid. Because the heat generation element is in direct contact with the cooling liquid, the heat dissipation efficiency is higher, and the noise is lower. The immersion cooling of a data center, for example, can aid in improving its heat dissipation design by directly immersing the information technology (IT) hardware in a liquid. The heat generated by the electronic components is transferred directly and efficiently into the liquid, thereby reducing the need for actively cooling components such as thermally conductive interface materials, heat sinks, and fans. These improvements enhance energy efficiency while allowing higher encapsulation density, reducing the energy consumption of the server cooling, helping to create a more environmentally friendly data center, and reducing the number of moving parts that need to be repaired and replaced.

The immersive liquid cooling agent is an insulation cooling liquid, which is generally composed of silicon oil, mineral oil, fluorinated liquid, and other substances, it is characterized in that the immersive liquid cooling agent is completely insulated and non-corrosive, even if an electronic component is immersed therein for more than 20 years, it will not impose any influence on the electronic component; the high-efficient heat dissipation can allow the computer lab to omit the large-scale refrigeration plant such as air conditioner, and save more than 75% of the space, and its Power Usage Effectiveness (PUE) approaches 1.0, thereby exerting the maximum computing power with the limited electric power. Depending on the type of coolant, the coolants can be divided into a single-phase coolant and a two-phase coolant, wherein the single-phase coolant is only a liquid, the two-phase coolant can produce both a liquid state and a gaseous state. The heat dissipation may be performed by using a dry cooler, a cooling tower, and the like. Liquid cooling has an operation history of 10 years on the international market, among the manufacturers of immersion cooling products for data centers, the products from the Minnesota Mining and Manufacturing Corporation (3M Corporation) are dominated by the two-phase coolant (the key product is fluorinated liquid), which has gained an early use in the encrypted money mining with a high power density. CN108351674A discloses an immersion cooling system using a fluorinated liquid manufactured by the 3M Corporation, the fluorinated liquid is a fluorine-based inert liquid completely composed of a fluoride (i.e., perfluorinated compound), mainly a perfluoroamine compound. CN112135811A discloses a perfluorinated amino olefin compound represented by the general formula CFY═CXN(Rf)CF₂Rf′, which can be used in immersion cooling. CN111475002A discloses a cooling liquid containing a perfluoroamine compound as the main component, the perfluoroamine compound is one of perfluorotriethylamine, perfluorotripropylamine, perfluorotributylamine, perfluorotripentylamine and perfluoro-N-methylmorpholine or a mixture thereof, it can be used in a cooling system of electronic equipment.

However, the liquid cooling agent in the prior art generally has the defect of poor compatibility between a component of the liquid cooling agent and an electronic device material, its application scenarios and conditions are very limited. Therefore, the properties of the liquid cooling agent for electronic devices need to be further improved.

### SUMMARY

The present disclosure provides a composition, a liquid cooling agent and application thereof, and an immersion cooling system, thereby solving the existing problem of poor compatibility between a component of the liquid cooling agent and an electronic device material in the prior art; the liquid cooling agent of the present disclosure has good fluidity and excellent heat-dissipation performance, improves the compatibility between the component of the liquid cooling agent and the electronic device material, and protects an electronic device from being damaged.

In order to fulfill the purpose, the present disclosure mainly provides the following technical scheme:

The examples of the present disclosure provide a composition, which is a perfluoropolyether compound represented by a structural general formula A-(R_{CF}O)ₙ—(CF₂O)ₘ—(CF₂)_{z}—B, or a combination of the perfluoropolyether compound and perfluoropolyether diol represented by a structural general formula HO—CH₂—(CF₂)_{q}—(R_{CF}O)ₙ—(CF₂O)ₘ—(CF₂)_{z}—CH₂OH;

wherein the groups (R_{CF}O) and (CF₂O) are randomly distributed;

A is a group —F, —CF₃, CF₃CF₂—, CF₃—O—, or CF₃CF₂—O—; B is a group —CF₃ or —CF₂CF₃; R_{CF} is a group —CF₂CF₂—, —CF₂CF₂CF₂—, or —CF(CF₃)CF₂—;

z is an integer between 0 and 2, n and m are both integers greater than 0, the sum n+m is within a range of 2-30, the ratio n/nm is within a range of 1-30, q is an integer greater than 0.

Preferably, the perfluoropolyether compound is represented by a structural general formula A-(R_{CF}O)ₙ—(CF₂O)ₘ—(CF₂)_{z}—B, wherein A, B, and R_{CF} are the following groups, respectively:
(1) when A is a group —F, —CF₃, CF₃CF₂—, CF₃—O—, or CF₃CF₂—O—, B is a group —CF₃, R_{CF} is a group —CF₂CF₂—;
or (2) when A is a group —F, —CF₃, CF₃CF₂—, CF₃—O—, or CF₃CF₂—O—, B is a group —CF₃, R_{CF} is a group —CF₂CF₂CF₂—;
or (3) when A is a group —F, —CF₃, CF₃CF₂—, CF₃—O—, or CF₃CF₂—O—, B is a group —CF₃, R_{CF} is a group —CF(CF₃)CF₂—;
or (4) when A is a group —F, —CF₃, CF₃CF₂—, CF₃—O—, or CF₃CF₂—O—, B is a group —CF₂CF₃, R_{CF} is a group —CF₂CF₂—;
or (5) when A is a group —F, —CF₃, CF₃CF₂—, CF₃—O—, or CF₃CF₂—O—, B is a group —CF₂CF₃, R_{CF} is a group —CF₂CF₂CF₂—;
or (6) when A is a group —F, —CF₃, CF₃CF₂—, CF₃—O—, or CF₃CF₂—O—, B is a group —CF₂CF₃, R_{CF} is a group —CF(CF₃)CF₂—.

Preferably, the perfluoropolyether compound is represented by a structural general formula A-(R_{CF}O)ₙ—(CF₂O)ₘ—(CF₂)_{z}—B, wherein A is a group CF₃—O—; B is a group —CF₂CF₃; R_{CF} is a group —CF(CF₃)CF₂—; z is 1.

Preferably, the weight percentage of perfluoropolyether diol represented by a structural general formula HO—CH₂—(CF₂)_{q}—(R_{CF}O)ₙ—(CF₂O)ₘ—(CF₂)_{z}—CH₂OH in the composition is not more than 5%.

Preferably, the composition is used as a cooling medium.

Preferably, the composition is present in the cooling medium in a content of at least 25% by weight.

The examples of the present disclosure also provide a liquid cooling agent comprising a perfluoropolyether compound represented by a structural general formula A-(R_{CF}O)ₙ—(CF₂O)ₘ—(CF₂)_{z}—B, or a combination of the perfluoropolyether compound and perfluoropolyether diol represented by a structural general formula HO—CH₂—(CF₂)_{q}—(R_{CF}O)ₙ—(CF₂O)ₘ—(CF₂)_{z}—CH₂OH;

wherein the groups (R_{CF}O) and (CF₂O) are randomly distributed;

A is a group —F, —CF₃, CF₃CF₂—, CF₃—O—, or CF₃CF₂—O—; B is a group —CF₃ or —CF₂CF₃; R_{CF} is a group —CF₂CF₂—, —CF₂CF₂CF₂—, or —CF(CF₃)CF₂—;

z is an integer between 0 and 2, n and m are both integers greater than 0, the sum n+m is within a range of 2-30, the ratio n/m is within a range of 1-30, q is an integer greater than 0.

Preferably, the perfluoropolyether compound is represented by a structural general formula A-(R_{CF}O)ₙ—(CF₂O)ₘ—(CF₂)_{z}—B, wherein A, B, and R_{CF} are the following groups, respectively:
(1) when A is a group —F, —CF₃, CF₃CF₂—, CF₃—O—, or CF₃CF₂—O—, B is a group —CF₃, R_{CF} is a group —CF₂CF₂—;
or (2) when A is a group —F, —CF₃, CF₃CF₂—, CF₃—O—, or CF₃CF₂—O—, B is a group —CF₃, R_{CF} is a group —CF₂CF₂CF₂—;
or (3) when A is a group —F, —CF₃, CF₃CF₂—, CF₃—O—, or CF₃CF₂—O—, B is a group —CF₃, R_{CF} is a group —CF(CF₃)CF₂—;
or (4) when A is a group —F, —CF₃, CF₃CF₂—, CF₃—O—, or CF₃CF₂—O—, B is a group —CF₂CF₃, R_{CF} is a group —CF₂CF₂—;
or (5) when A is a group —F, —CF₃, CF₃CF₂—, CF₃—O—, or CF₃CF₂—O—, B is a group —CF₂CF₃, R_{CF} is a group —CF₂CF₂CF₂—;
or (6) when A is a group —F, —CF₃, CF₃CF₂—, CF₃—O—, or CF₃CF₂—O—, B is a group —CF₂CF₃, R_{CF} is a group —CF(CF₃)CF₂—.

Preferably, the perfluoropolyether compound is represented by the structural general formula A-(R_{CF}O)ₙ—(CF₂O)ₘ—(CF₂)_{z}—B, wherein A is a group CF₃—O—; B is a group —CF₂CF₃; R_{CF} is a group —CF(CF₃)CF₂—; z is 1.

Preferably, the weight percentage of the perfluoropolyether diol is not more than 5% in the combination of the perfluoropolyether compound represented by the structural general formula A-(R_{CF}O)ₙ—(CF₂O)ₘ—(CF₂)_{z}—B and the perfluoropolyether diol represented by the structural general formula HO—CH₂—(CF₂)_{q}—(R_{CF}O)ₙ—(CF₂O)ₘ—(CF₂)_{z}—CH₂OH.

The examples of the present disclosure further provide use of the aforementioned composition or liquid cooling agent in a cooling system of an electronic device.

Preferably, the electronic device comprises a computer server.

Preferably, the electronic device comprises a data center.

Preferably, the data center comprises centrally managed computing resources, equipment of the associated support systems, or a part of the data center, and modular components providing the data center together with other modules.

Preferably, the electronic device comprises one or more selected from the group consisting of a microprocessor, a semiconductor wafer for manufacturing a semiconductor device, a power control semiconductor, an electrochemical cell, a distribution switching gear, a power transformer, a circuit board, a multi-chip module, a packaged or unpackaged semiconductor device, a fuel cell, or a laser.

Preferably, the electronic device is partially or fully immersed in a cooling medium comprising the composition or the liquid cooling agent, such that the electronic device performs heat exchange with the cooling medium.

Preferably, the composition or the liquid cooling agent is present in the cooling medium in a content of at least 25% by weight.

Preferably, the cooling system of an electronic device is a single-phase immersion cooling system.

The examples of the present disclosure further provide an immersion cooling system comprising:

a fully enclosed or incompletely enclosed housing having an inner space;

a heat-generating component disposed in the inner space;

and a cooling medium liquid disposed in the inner space, such that the heat-generating component contacts with the cooling medium liquid;

wherein the cooling medium comprises the aforementioned composition or the aforementioned liquid cooling agent.

Preferably, the composition or liquid cooling agent is present in the cooling medium in a content of at least 25% by weight.

Preferably, the heat-generating component comprises an electronic device.

Preferably, the electronic device comprises a computer server.

Preferably, the electronic device comprises a data center.

Preferably, the data center comprises centrally managed computing resources, equipment of the associated support systems, or a part of the data center, and modular components providing the data center together with other modules.

Preferably, the electronic device comprises one or more selected from the group consisting of a microprocessor, a semiconductor wafer for manufacturing a semiconductor device, a power control semiconductor, an electrochemical cell, a distribution switching gear, a power transformer, a circuit board, a multi-chip module, a packaged or unpackaged semiconductor device, a fuel cell, or a laser.

Preferably, the heat-generating component is partially or fully immersed in the cooling medium.

Preferably, the immersion cooling system is a single-phase immersion cooling system.

In the present disclosure, the numerical range denoted by endpoints includes all numerical values contained in that range (e.g., the range of 1 to 5 includes 1, 1.5, 2, 2.75, 3, 3.8, 4, and 5).

Unless otherwise indicated, all numbers expressing quantities or ingredients, property measurements and so forth used in the specification and embodiments shall be understood as being modified by the term “about” in all instances. Accordingly, unless otherwise specified, the numerical parameters set forth in the lists of the foregoing specification and attached embodiments may vary depending upon the desired properties sought to be obtained by those skilled in the art by utilizing the teaching contents of the present disclosure. At the very least, and in the case of not seeking to limit the application of the doctrine of equivalents to the protection scope of the embodiments claimed by the claims, each numerical parameter should at least be construed in light of the number of significant digits of the reported numerical range and by applying the conventional rounding method.

One or more technical schemes provided in the examples of the present disclosure at least produce the following technical effects or advantages:

the perfluoropolyether compound with the specific polymeric structure provided by the present disclosure has characteristics such as high electrical insulation performance, low viscosity, high boiling point, high thermal conductivity, non-toxicity, and incombustibility, and when the perfluoropolyether compound is used as a liquid cooling agent in a cooling system of an electronic device, it has excellent heat-dissipation performance and desirable compatibility and stability, it can protect an electronic device from being damaged, and has a long service life.

### BRIEF DESCRIPTION OF THE DRAWINGS

The accompanying drawings serve to facilitate the further comprehension of the present disclosure and constitute a part of the specification, the drawings and the following detailed description are used for explaining the present disclosure, instead of imposing a limitation thereto. In the accompanying drawings:

FIG. 1 is a physical map of an electronic device sample-1 in the compatibility testing 1 in examples of the present disclosure;

FIG. 1-1a and FIG. 1-1b illustrate a physical comparison graph and an infrared spectrogram comparison graph of part-1 of the electronic device sample-1 in examples of the present disclosure before and after immersion in perfluoropolyether, respectively;

FIG. 1-2a and FIG. 1-2b illustrate a physical comparison graph and an infrared spectrogram comparison graph of part-2 of the electronic device sample-1 in examples of the present disclosure before and after immersion in perfluoropolyether, respectively;

FIG. 1-3a and FIG. 1-3b illustrate a physical comparison graph and an infrared spectrogram comparison graph of part-1 of the electronic device sample-1 in examples of the present disclosure before and after immersion in perfluoropolyether, respectively;

FIG. 1-4a and FIG. 1-4b illustrate a physical comparison graph and an infrared spectrogram comparison graph of part-1 of the electronic device sample-1 in examples of the present disclosure before and after immersion in perfluoropolyether, respectively;

FIG. 2 is a physical map of an electronic device sample-2 in the compatibility testing in examples of the present disclosure;

FIG. 2-a and FIG. 2-b illustrate a physical comparison graph and an infrared spectrogram comparison graph of the electronic device sample-2 in examples of the present disclosure before and after immersion in perfluoropolyether, respectively;

FIG. 3 is a physical map of an electronic device sample-3 in the compatibility testing in examples of the present disclosure;

FIG. 3-a and FIG. 3-b illustrate a physical comparison graph and an infrared spectrogram comparison graph of the electronic device sample-3 in examples of the present disclosure before and after immersion in perfluoropolyether, respectively;

FIG. 4 is a diagram showing a testing apparatus for compatibility testing 2 in examples of the present disclosure;

FIG. 5 illustrates an infrared spectrogram comparison graph of perfluoropolyether before and after use in the compatibility testing 2 of the present disclosure.

### DETAILED DESCRIPTION

In order to facilitate comprehension of the technical schemes of the present application by those skilled in the art, the technical schemes of the present application are further formulated with reference to specific examples, it should be understood that the examples of the present application serve to explain the schemes of the present application, instead of imposing limitation to the protection scope of the present application.

The examples of the present disclosure provide a composition, a liquid cooling agent and use thereof in a cooling system of an electronic device, and an immersion cooling system, thereby solving the existing problem of poor compatibility between a component of the liquid cooling agent and an electronic device material in the prior art; the liquid cooling agent of the present disclosure has good fluidity and excellent heat-dissipation performance, improves the compatibility between the component of the liquid cooling agent and the electronic device material, and protects an electronic device from being damaged.

The examples of the present disclosure provide a composition, which is a perfluoropolyether compound represented by a structural general formula A-(R_{CF}O)ₙ—(CF₂O)ₘ—(CF₂)_{z}—B, or a combination of the perfluoropolyether compound and perfluoropolyether diol represented by a structural general formula HO—CH₂—(CF₂)_{q}—(R_{CF}O)ₙ—(CF₂O)ₘ—(CF₂)_{z}—CH₂OH;

wherein the groups (R_{CF}O) and (CF₂O) are randomly distributed;

A is a group —F, —CF₃, CF₃CF₂—, CF₃—O—, or CF₃CF₂—O—; B is a group —CF₃ or —CF₂CF₃; R_{CF} is a group —CF₂CF₂—, —CF₂CF₂CF₂—, or —CF(CF₃)CF₂—;

z is an integer between 0 and 2, n and m are both integers greater than 0, the sum n+m is within a range of 2-30, the ratio n/m is within a range of 1-30, q is an integer greater than 0.

In the structural general formula of the perfluoropolyether compound or perfluoropolyether diol described above, “the groups (R_{CF}O) and (CF₂O) are randomly distributed” refers to that the positions of the groups (R_{CF}O) and (CF₂O) in the chain segments of n and m are randomly distributed, including that their sequences are freely interchangeable, and the monomer units may be arranged in block copolymer.

In some preferred examples of the present disclosure, the perfluoropolyether compound is represented by a structural general formula A-(R_{CF}O)ₙ—(CF₂O)ₘ—(CF₂)_{z}—B, wherein A, B, and R_{CF} are the following groups, respectively:
(1) when A is a group —F, —CF₃, CF₃CF₂—, CF₃—O—, or CF₃CF₂—O—, B is a group —CF₃, R_{CF} is a group —CF₂CF₂—;
or (2) when A is a group —F, —CF₃, CF₃CF₂—, CF₃—O—, or CF₃CF₂—O—, B is a group —CF₃, R_{CF} is a group —CF₂CF₂CF₂—;
or (3) when A is a group —F, —CF₃, CF₃CF₂—, CF₃—O—, or CF₃CF₂—O—, B is a group —CF₃, R_{CF} is a group —CF(CF₃)CF₂—;
or (4) when A is a group —F. —CF₃, CF₃CF₂—, CF₃—O—, or CF₃CF₂—O—, B is a group —CF₂CF₃, R_{C}F is a group —CF₂CF₂—;
or (5) when A is a group —F, —CF₃, CF₃CF₂—, CF₃—O—, or CF₃CF₂—O—, B is a group —CF₂CF₃, R_{CF} is a group —CF₂CF₂CF₂—;
or (6) when A is a group —F, —CF₃, CF₃CF₂—, CF₃—O—, or CF₃CF₂—O—, B is a group —CF₂CF₃, R_{CF} is a group —CF(CF₃)CF₂—.

In some preferred examples of the present disclosure, the perfluoropolyether compound is represented by a structural general formula A-(R_{CF}O)ₙ—(CF₂O)ₘ—(CF₂)_{z}—B, wherein A is a group CF₃—O—; B is a group —CF₂CF₃; R is a group —CF(CF₃)CF₂—; z is 1.

In some preferred examples of the present disclosure, the perfluoropolyether compound represented by a structural general formula A-(R_{CF}O)ₙ—(CF₂O)ₘ—(CF₂)_{z}—B and the perfluoropolyether diol represented by a structural general formula HO—CH₂—(CF₂)_{q}—(R_{CF}O)ₙ—(CF₂O)ₘ—(CF₂)_{z}—CH₂OH in the composition may be combined in any ratio, for example, the weight ratio of the perfluoropolyether compound represented by a structural general formula A-(R_{CF}O)ₙ—(CF₂O)ₘ—(CF₂)_{z}—B and the perfluoropolyether diol represented by a structural general formula HO—CH₂—(CF₂)_{q}—(R_{CF}O)ₙ—(CF₂O)ₘ—(CF₂)_{z}—CH₂OH is within a range of 99:1-1:99; the weight percentage of perfluoropolyether diol represented by a structural general formula HO—CH₂—(CF₂)_{q}—(R_{CF}O)ₙ—(CF₂O)ₘ—(CF₂)_{z}—CH₂OH in the composition is preferably not more than 10%, more preferably not more than 5%.

In some preferred examples of the present disclosure, the composition is used as a cooling medium.

In some preferred examples of the present disclosure, the composition is present in the cooling medium in a content of at least 25% by weight.

The examples of the present disclosure provide a liquid cooling agent, comprising a perfluoropolyether compound represented by a structural general formula A-(R_{CF}O)ₙ—(CF₂O)ₘ—(CF₂)_{z}—B, or a combination of the perfluoropolyether compound and perfluoropolyether diol represented by a structural general formula HO—CH₂—(CF₂)_{q}—(R_{CF}O)ₙ—(CF₂O)ₘ—(CF₂)_{z}—CH₂OH;

wherein the groups (R_{CF}O) and (CF₂O) are randomly distributed;

A is a group —F, —CF₃, CF₃CF₂—, CF₃—O—, or CF₃CF₂—O—; B is a group —CF₃ or —CF₂CF₃; R_{CF} is a group —CF₂CF₂—, —CF₂CF₂CF₂—, or —CF(CF₃)CF₂—;

z is an integer between 0 and 2, n and in are both integers greater than 0, the sum n+m is within a range of 2-30, the ratio n/m is within a range of 1-30, q is an integer greater than 0.

In some preferred examples of the present disclosure, the perfluoropolyether compound is represented by a structural general formula A-(R_{CF}O)ₙ—(CF₂O)ₘ—(CF₂)_{z}—B, wherein A, B, and R_{CF} are the following groups, respectively:
(1) when A is a group —F, —CF₃, CF₃CF₂—, CF₃—O—, or CF₃CF₂—O—, B is a group —CF₃, R_{CF} is a group —CF₂CF₂—;
or (2) when A is a group —F. —CF₃, CF₃CF₂—, CF₃—O—, or CF₃CF₂—O—, B is a group —CF₃, R_{CF} is a group —CF₂CF₂CF₂—;
or (3) when A is a group —F, —CF₃, CF₃CF₂—, CF₃—O—, or CF₃CF₂—O—, B is a group —CF₃, R_{CF} is a group —CF(CF₃)CF₂—;
or (4) when A is a group —F, —CF₃, CF₃CF₂—, CF₃—O—, or CF₃CF₂—O—, B is a group —CF₂CF₃, R_{CF} is a group —CF₂CF₂—;
or (5) when A is a group —F, —CF₃, CF₃CF₂—, CF₃—O—, or CF₃CF₂—O—, B is a group —CF₂CF₃, R_{CF} is a group —CF₂CF₂CF₂—;
or (6) when A is a group —F, —CF₃, CF₃CF₂—, CF₃—O—, or CF₃CF₂—O—, B is a group —CF₂CF₃, R_{CF} is a group —CF(CF₃)CF₂—.

In some preferred examples of the present disclosure, the perfluoropolyether compound is represented by the structural general formula A-(R_{CF}O)ₙ—(CF₂O)ₘ—(CF₂)_{z}—B, wherein A is a group CF₃—O—; B is a group —CF₂CF₃; R_{CF} is a group —CF(CF₃)CF₂—; z is 1.

In some examples of the present disclosure, the perfluoropolyether compound represented by a structural general formula A-(R_{CF}O)ₙ—(CF₂O)ₘ—(CF₂)_{z}—B and the perfluoropolyether diol represented by a structural general formula HO—CH₂—(CF₂)_{q}—(R_{CF}O)ₙ—(CF₂O)ₘ—(CF₂)_{z}—CH₂OH in the liquid cooling agent may be combined in any ratio, for example, the weight ratio of the perfluoropolyether compound represented by a structural general formula A-(R_{CF}O)ₙ—(CF₂O)ₘ—(CF₂)_{z}—B and the perfluoropolyether diol represented by a structural general formula HO—CH₂—(CF₂)_{q}—(R_{CF}O)ₙ—(CF₂O)ₘ—(CF₂)_{z}—CH₂OH is within a range of 99:1-1:99; the weight percentage of perfluoropolyether diol represented by a structural general formula HO—CH₂—(CF₂)_{q}—(R_{CF}O)ₙ—(CF₂O)ₘ—(CF₂)_{z}—CH₂OH in the composition is preferably not more than 10%, more preferably not more than 5%.

In some examples of the present disclosure, the perfluoropolyether compound in the composition or the liquid cooling agent provided by the present disclosure can be obtained through the following preparation method:

reacting hexafluoropropylene in the presence of oxygen gas and an initiator to obtain perfluoropolyether peroxide; subjecting the perfluoropolyether peroxide to heat treatment to eliminate the peroxide group in the perfluoropolyether peroxide, to obtain the perfluoropolyether containing acyl fluorine groups; carrying out end group treatment by using fluorine gas to remove acyl fluorine groups as the end groups, finally performing fractional distillation and cutting, and collecting distillate to obtain the perfluoropolyether compound represented by a structural general formula A-(R_{CF}O)ₙ—(CF₂O)ₘ—(CF₂)_{z}—B, or reducing the perfluoropolyether containing the acyl fluorine groups to obtain the perfluoropolyether alcohol compound represented by a structural general formula HO—CH₂—(CF₂)_{q}—(R_{CF}O)ₙ—(CF₂O)ₘ—(CF₂)_{z}—CH₂OH.

The perfluoropolyether compound with the specific polymeric structure provided by the present disclosure has the characteristics such as high electrical insulation performance, low viscosity, high boiling point, high thermal conductivity, non-toxicity, and incombustibility, and when the perfluoropolyether compound is used as a liquid cooling agent in a cooling system of an electronic device, it has excellent heat-dissipation performance and desirable compatibility and stability, it can protect an electronic device from being damaged, and has a long service life.

The perfluoropolyether compound provided by the examples of the present disclosure has good material compatibility, and the compound does not cause swelling corrosion to chips and wirings in equipment even if the chips and wirings are in contact with the compound for a long time, thus the perfluoropolyether compound can be applied on various sensitive materials, including but not limited to aluminum, polymethyl methacrylate (PMMA), butyl rubber, copper, polyethylene (PE), natural rubber, carbon steel, polypropylene, nitrile rubber, 302 stainless steel, polycarbonate, ethylene propylene diene monomer, brass, polyester, molybdenum, epoxy resin, tantalum, polyethylene terephthalate (PET), tungsten, phenolic resin, copper alloy C172, Acrylonitrile Butadiene Styrene (ABS), and magnesium alloy AZ32B.

In some examples of the present disclosure, the composition or liquid cooling agent provided by the present disclosure can be used in a cooling system of an electronic device.

In some examples of the present disclosure, the electronic device may comprise a computer server; and may also comprise a data center, particularly the data center operating at a frequency higher than 3 GHz. Among other things, the data center comprises centrally managed computing resources, equipment of the associated support systems, or a part of the data center, and modular components providing the data center together with other modules. The electronic device comprises one or more selected from the group consisting of a microprocessor, a semiconductor wafer for manufacturing a semiconductor device, a power control semiconductor, an electrochemical cell, a distribution switching gear, a power transformer, a circuit board, a multi-chip module, a packaged or unpackaged semiconductor device, a fuel cell, or a laser.

In some examples of the present disclosure, when the composition or liquid cooling agent is used in a cooling system for an electronic device, an immersion cooling system is adopted. Specifically, the electronic device is partially or fully immersed in a cooling medium comprising the composition or the liquid cooling agent, such that the electronic device performs heat exchange with the cooling medium.

In some examples of the present disclosure, the composition or the liquid cooling agent provided by the present disclosure is present in the cooling medium in a content of at least 25% by weight, for example, the cooling medium comprises at least 25% by weight, at least 35% by weight, at least 45% by weight, at least 65% by weight, at least 85% by weight, or 100% by weight of the composition or liquid cooling agent. In addition to the liquid cooling agent described above, the cooling medium may also contain one or more of the following components in an amount up to 75% by weight, based on the total weight of the cooling medium: ethers, alkanes, perfluoroolefins, olefins, halogenated olefins, perfluorocarbons, perfluorinated tertiary amines, perfluorinated ethers, cycloalkanes, esters, perfluorinated ketones, ketone, ethylene oxide, aromatic compounds, siloxanes, hydrochlorocarbons, hydrochlorofluorocarbons, hydrofluorocarbons, hydrofluoroolefins, hydrochloroolefins, hydrochlorofluoroolefins, hydrofluoroethers, or mixtures thereof; or alkanes, perfluoroolefins, halogenated olefins, perfluorocarbons, perfluorinated tertiary amines, perfluorinated ethers, cycloalkanes, perfluorinated ketones, aromatic compounds, siloxanes, hydrochlorocarbons, hydrochlorofluorocarbons, hydrofluorocarbons, hydrofluoroolefins, hydrochlorofluoroolefins, hydrofluoroethers, or mixtures thereof, based on the total weight of the working fluid. Such additional components may be selected to modify or enhance the properties of the composition for a particular use.

In some examples of the present disclosure, the electronic device cooling system is a single-phase immersion cooling system.

Examples of the present disclosure also provide an immersion cooling system operable as a cooling system for cooling one or more heat-generating components. The immersion cooling system comprises: a fully, enclosed or incompletely enclosed housing having an inner space; a heat-generating component disposed in the inner space; and a cooling medium liquid disposed in the inner space, such that the heat-generating component contacts with the cooling medium liquid; wherein the cooling medium comprises the aforementioned composition or liquid cooling agent provided by the present disclosure.

In some examples of the present disclosure, the composition or liquid cooling agent is present in the cooling medium in a content of at least 25% by weight.

In some examples of the present disclosure, the heat-generating component may be partially or fully immersed in the liquid of the cooling medium when the heat-generating component is disposed in the inner space.

In some examples of the present disclosure, the heat-generating component may comprise one or more electronic devices. The electronic device may be a computer server, a data center, or the like. In particular, the electronic device may be a data center, particularly the data center operating at a frequency higher than 3 GHz. The data center comprises centrally managed computing resources, equipment of the associated support systems, or a part of the data center, and modular components providing the data center together with other modules.

In some examples of the present disclosure, the electronic device further comprises one or more selected from the group consisting of a microprocessor, a semiconductor wafer for manufacturing a semiconductor device, a power control semiconductor, an electrochemical cell, a distribution switching gear, a power transformer, a circuit board, a multi-chip module, a packaged or unpackaged semiconductor device, a fuel cell, or a laser.

In some examples of the present disclosure, the immersion cooling system is a single-phase immersion cooling system. The immersion cooling system, when operating with a single-phase immersion cooling mode, may further include a pump and a heat exchanger, the pump is operated to move the cooling medium to the heat-generating component, and the heat exchanger and drives the cooling medium from the heat-generating component and the heat exchanger, the heat exchanger is operated to cool the medium. The heat exchanger may be disposed inside or outside of the housing.

The examples of the present disclosure also provide a method for cooling a heat-generating component comprising partially or completely immersing the heat-generating component in the cooling medium comprising the composition or the liquid cooling agent, such that the electronic device performs heat exchange with the cooling medium.

In order to better understand the technical schemes, the technical schemes will be described in detail below with reference to the accompanying drawings and specific embodiments of the specification, but the technical schemes do not impose limitation to the present disclosure.

### EXAMPLES

Table 1 below illustrates a comparison table of basic physicochemical properties of the perfluoropolyether compound provided by examples of the present disclosure and the commercially available liquid cooling agent products.

TABLE 1
Comparison table of basic physicochemical properties of the perfluoropolyether
compound and the commercially available liquid cooling agent

| | Example 1 | Example 2 |
|---|---|---|
| Structural formula or | CF₃O—(CF(CF₃)CF₂O)ₙ—(CF₂O)ₘ—(CF₂)—CF₂CF₃, | CF₃CF₂O—(CF₂CF₂CF₂O)ₙ—(CF₂O)ₘ—CF₃, |
| name | m = 29, n = 1 | m = 15, n = 15 |
| Boiling point (° C.) | 1229 | 853 |
| Physical state at | Liquid | Liquid |
| normal temperature | | |
| Color | Colorless and | Colorless and |
| | transparent | transparent |
| Toxicity | Non-toxicity | Non-toxicity |
| Flammability | Non-flammable | Non-flammable |
| Pour point (° C.) | −27 | −41 |
| Thermal conductivity | 0.356 | 0.341 |
| coefficient (25° C., | | |
| W/m · K) | | |
| Specific heat capacity | 1150 | 1151 |
| (25° C., J/(kg · ° C.)) | | |
| Volume | 4.46*10¹² | 3*10¹² |
| resistivity(Ω · cm) | | |

| | Example 3 | Example 4 |
|---|---|---|
| Structural formula or | CF₃—(CF₂CF₂O)ₙ—(CF₂O)ₘ—(CF₂)₂—CF₃, | CF₃CF₂—(CF(CF₃)CF₂O)ₙ—(CF₂O)ₘ—CF₂CF₃, |
| name | m = 15, n = 15 | m = 3, n = 1 |
| Boiling point (° C.) | 683 | 125 |
| Physical state at | Liquid | Liquid |
| normal temperature | | |
| Color | Colorless and | Colorless and |
| | transparent | transparent |
| Toxicity | Non-toxicity | Non-toxicity |
| Flammability | Non-flammable | Non-flammable |
| Pour point (° C.) | −51 | −95 |
| Thermal conductivity | 0.313 | 0.382 |
| coefficient (25° C., | | |
| W/m · K) | | |
| Specific heat capacity | 1147 | 1198 |
| (25° C., J/(kg · ° C.)) | | |
| Volume | 2.8*10¹² | 9.8*10¹² |
| resistivity(Ω · cm) | | |

| | Commercially available liquid cooling agent | | | |
|---|---|---|---|---|
| Structural formula or | FC40 | Novec 7300 | Novec 7500 | Novec 7700 |
| name | | | | |
| Boiling point (° C.) | 165 | 98 | 128 | 167 |
| Physical state at | Liquid | Liquid | Liquid | Liquid |
| normal temperature | | | | |
| Color | Colorless and | Colorless and | Colorless and | Colorless and |
| | transparent | transparent | transparent | transparent |
| Toxicity | Non-toxicity | Non-toxicity | Non-toxicity | Non-toxicity |
| Flammability | Non-flammable | Non-flammable | Non-flammable | Non-flammable |
| Pour point (° C.) | −57 | −38 | −100 | −50 |
| Thermal conductivity | 0.067 | 0.063 | 0.065 | 0.064 |
| coefficient (25° C., | | | | |
| W/m · K) | | | | |
| Specific heat capacity | 1100 | 1140 | 1128 | 1040 |
| (25° C., J/(kg · ° C.)) | | | | |
| Volume | 10¹⁵ | 10¹¹ | 10⁸ | 10¹¹ |
| resistivity(Ω · cm) | | | | |

As can be seen from the physical data in Table 1, the perfluoropolyether compound provided in the examples of the present disclosure is non-toxic and non-flammable, it has sufficient safety performance, and its volume resistivity is much higher than the design requirement on the cooling liquid as stipulated in the “Design Specification of Single-phase Immersion Type Direct Liquid Cooling Data Center”, thus the compound has better electrical insulation performance. The thermal conductivity coefficient of the perfluoropolyether compounds provided by the present disclosure is more than 5 times of the commercially available liquid cooling agent, and the specific heat capacity of the perfluoropolyether compounds is more than 1,100 J/(kg·° C.), such that the perfluoropolyether compounds can provide more effective heat transfer, and when the perfluoropolyether compounds are used in a cooling system of a heat generating component, the compounds can provide a more effective cooling effect.

### Compatibility Testing 1:

The perfluoropolyether compounds provided by the present disclosure and an electronic device were subjected to compatibility testing, the adopted electronic device test samples were shown in Table 2, and the adopted test method was as follows:

### (1) High-Boiling Perfluoropolyether Testing Process

5 g of a material sample was weighted and placed in a 50 mL beaker, 50 g of high-boiling perfluoropolyether was added, the material sample was placed in an oven at 8° C. and subjected to immersion for 96 h, and the perfluoropolyether was collected after the material sample was taken out, the sample was cleaned and washed with the low-boiling perfluoropolyether for no more than 30 s, the residue polyether on the sample was subsequently sucked by using a filter paper, subjected to standing still at room temperature for 30 min, then subjected to the weight, volume, hardness change and infrared testing.

### (2) Low-Boiling Perfluoropolyether Testing Process

5 g of a material sample was weighted and placed in a Soxhlet extraction tube (if necessary, the sample was filled in a filter paper bucket), 100 mL of low-boiling perfluoropolyether was weighted and added into the Soxhlet extraction bottle (zeolite or a rotor was added in the extraction bottle). The Soxhlet extraction device was mounted, the cooling water was provided, the power supply of the oil bath pan was switched on, and the heating temperature (higher than the boiling point of polyether) was set. The material sample was subjected to heating reflux for 72 h. The perfluoropolyether was collected after the material sample was taken out, and the residue polyether on the sample was subsequently sucked by using a filter paper, subjected to standing still at room temperature for 30 min, then subjected to the weight, volume, hardness change, and infrared testing.

### (3) Test Items

a. Appearance:

The appearance of the samples and the liquid cooling agents before and after immersion were observed and recorded.

b. Weight Change:

the weights of the samples in the air before and after immersion were measured respectively according to the provisions of the China National Standard GB/T 1690, and the weight change percentage (ΔW) was calculated:

$$Δ W = \frac{{W}_{3} - {W}_{1}}{{W}_{1}} \times 100$$

in the formula: ΔW denoted the weight change percentage of the material sample, %;

W₁ denoted the weight of the material sample in the air before immersion, g;

W₃ denoted the weight of the material sample in the air after immersion, g.

c. Volume Change:

the weights of the test samples in the air and distilled water before and after immersion were measured respectively according to the provisions of the China National Standard GB/T 1690, and the volume change percentage (ΔV) was calculated:

$$Δ V = \frac{( {W}_{3} - {W}_{4} ) - ( {W}_{1} - {W}_{2} )}{{W}_{1} - {W}_{2}} \times 100$$

in the formula: ΔV denoted the volume change percentage of the test sample, %;

W₁ denoted the weight of the test sample in the air before immersion, g;

W₂ denoted the weight of the test sample in water before immersion, g;

W₃ denoted the weight of the test sample in the air after immersion, g;

W₄ denoted the weight of the test sample in water after immersion, g;

d. Hardness Change

The hardness of the test sample before and after immersion was measured according to the provisions of the China National Standard GB/T 6031, the hardness change ΔH=H₁−H₀ was obtained, where H₁ denoted the hardness before immersion, and H₀ denoted the hardness after immersion.

e. Infrared Scanning of Perfluoropolyether

The sample was coated on a potassium bromide window, and then placed in an infrared spectrometer and subjected to the infrared scanning measurement within the wave number range of 4000-400 cm⁻¹.

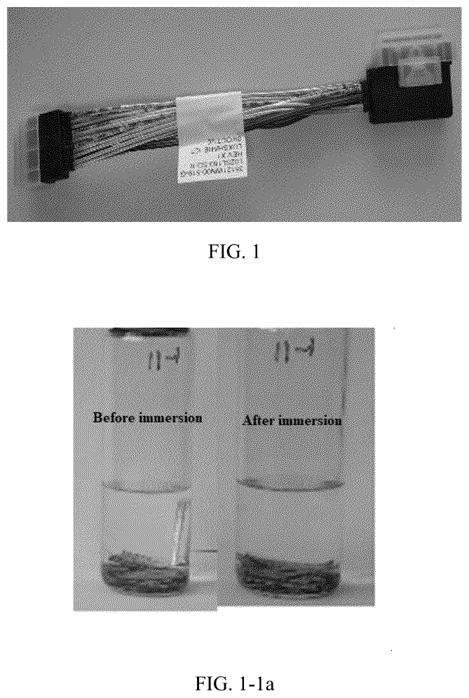

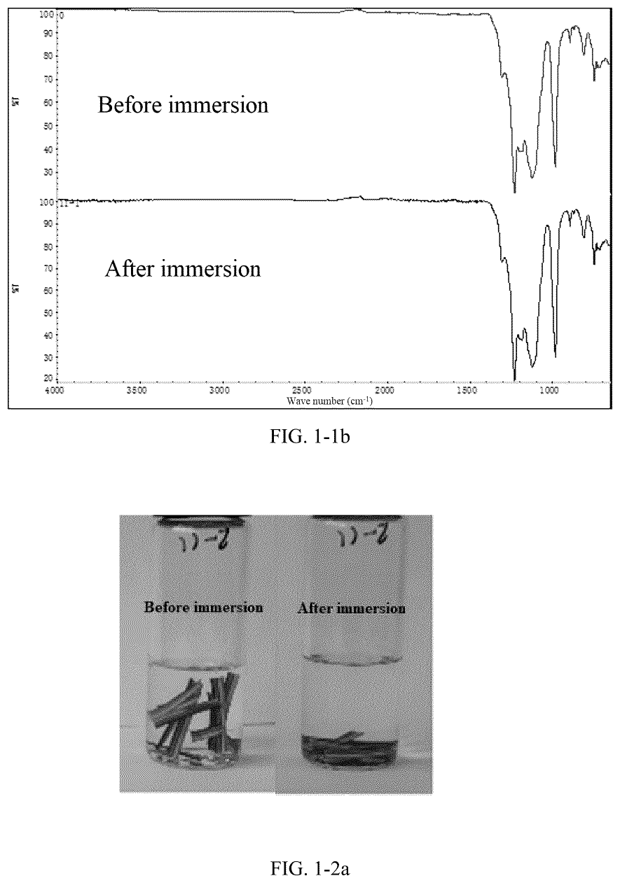

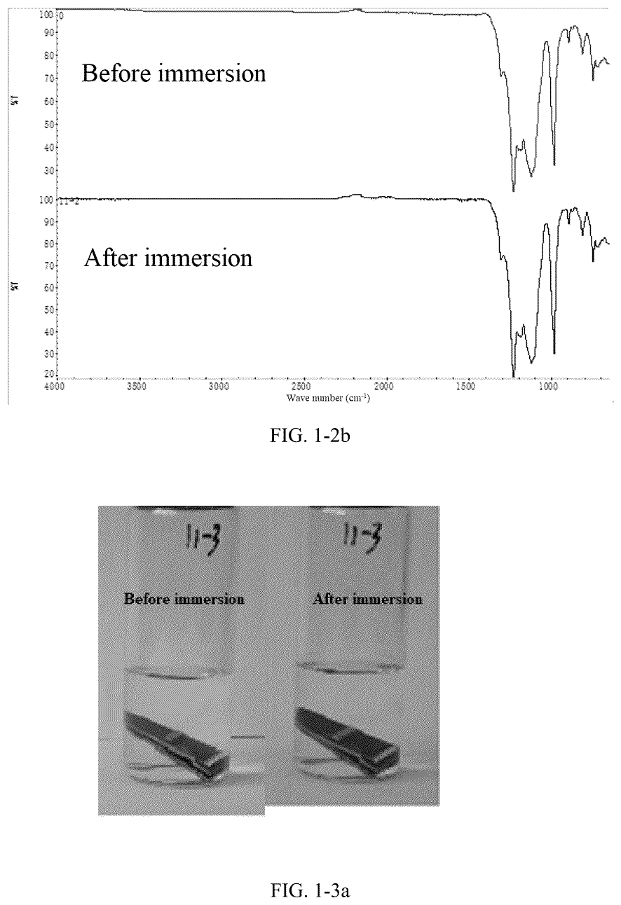

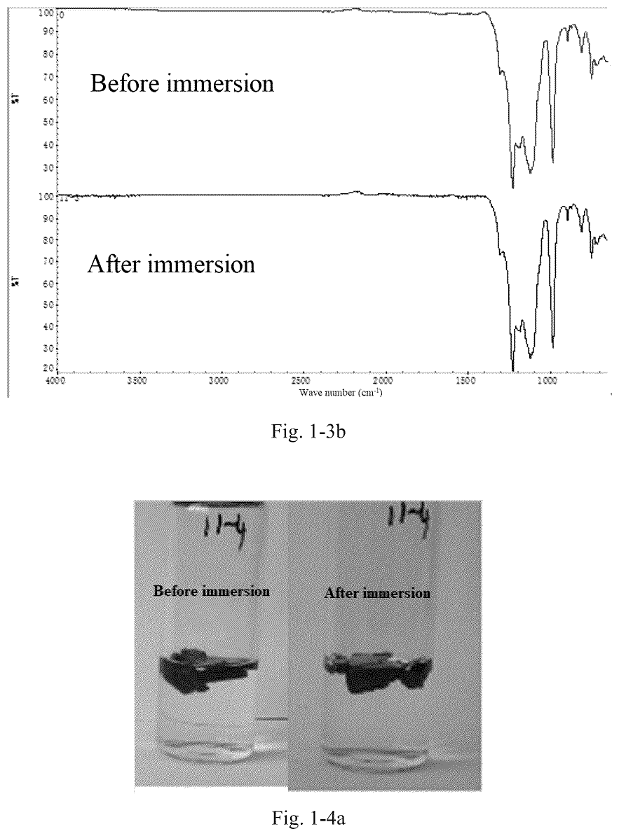

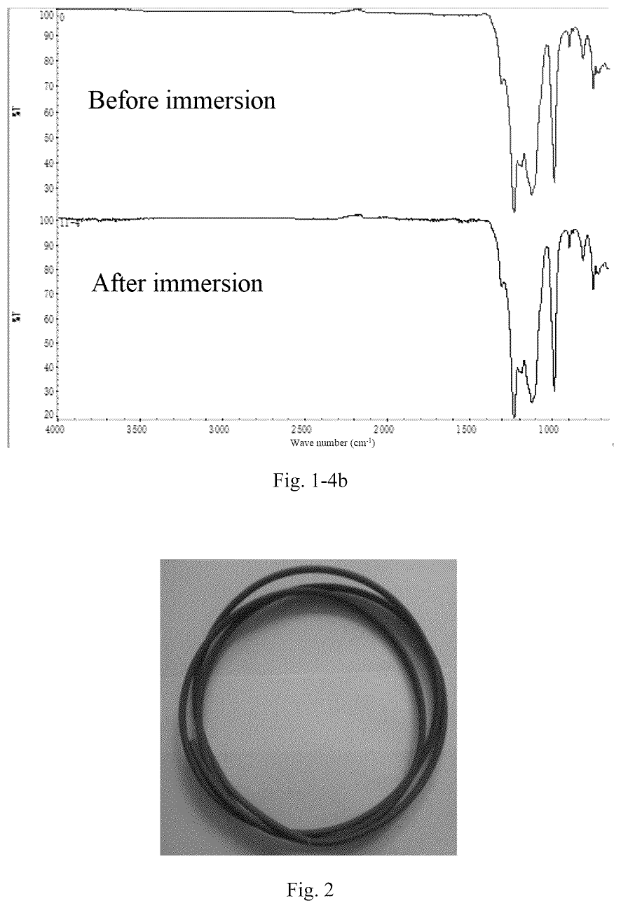

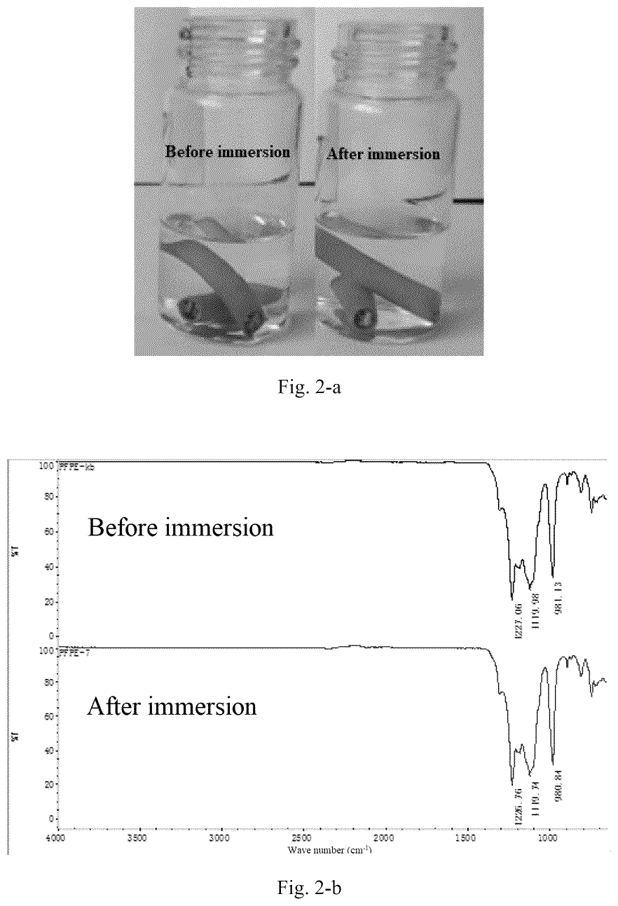

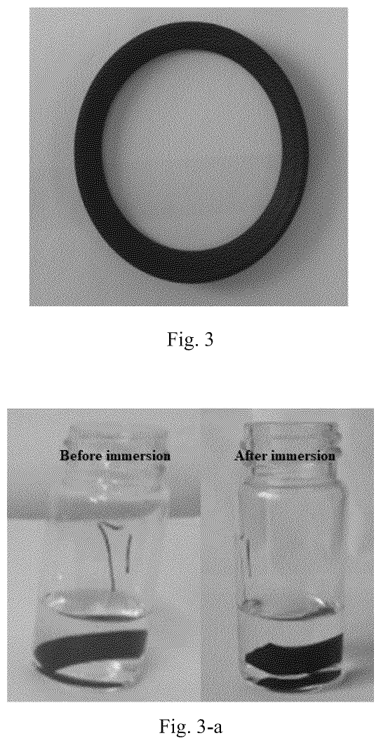

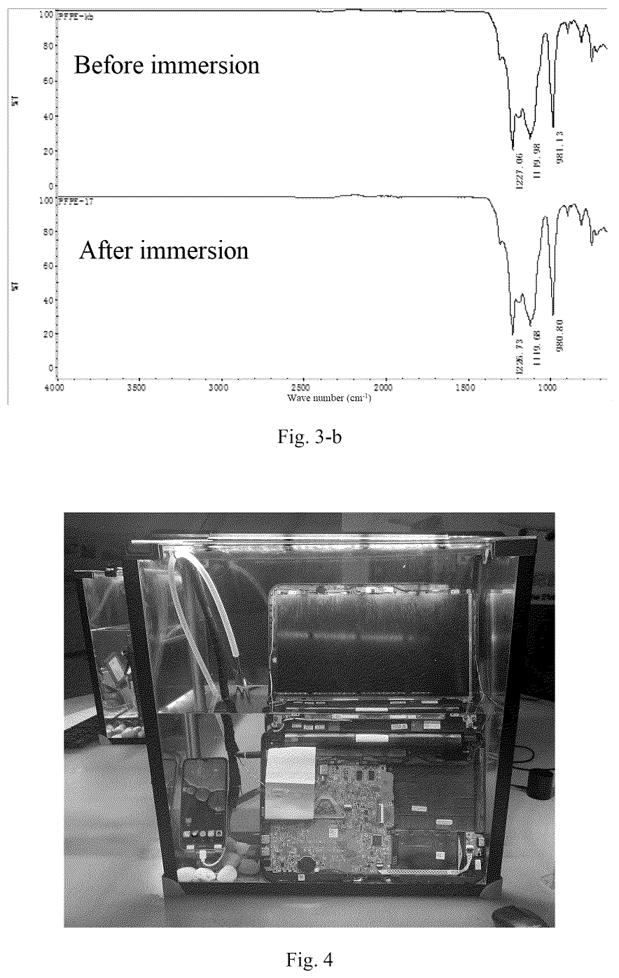

TABLE 2
The compatibility testing results of the perfluoropolyether liquid cooling agent provided by the present disclosure and electronic devices

| | | | | Volume | Weight |
|---|---|---|---|---|---|
| | | | | change of | change of |
| | | | | the sample | the sample |
| | | | Appearance | after | after |
| | | Part No. of the | change of | immersion | immersion |
| | | disassembled | liquid cooling | (%) (@80° | (%) (@80° |
| Perfluoropolyether compound | Source of samples | sample | agent | C., 96 h) | C., 96 h) |
| CF₃O—(CF(CF₃)CF₂O)ₙ—(CF₂O)ₘ—(CF₂)—CF₂CF₃, | Sample-1: | Part-1 | Clear | 0.55 | 0.6 |
| m = 10, n = 10 | Manufacturer | | (FIG. 1-1a) | | |
| | LUXSHARE-ICT, | Part-2 | Clear | 0.53 | 0.96 |
| | Specification REV | | (FIG. 1-2a) | | |
| | X1 (FIG. 1) | Part-3 | Clear | 0.05 | 0.17 |
| | | | (FIG. 1-3a) | | |
| | | Part-4 | Clear | 0.27 | 0.65 |
| | | | (FIG. 1-4a) | | |
| CF₃O—(CF(CF₃)CF₂O)ₙ—(CF₂O)ₘ—(CF₂)—CF₂CF₃, | Sample-2: PutianTefa | — | Clear | 0.45 | 0.18 |
| m = 10, n = 10 | finished network | | (FIG. 2-a) | | |
| | cable (FIG. 2) | | | | |
| CF₃O—(CF(CF₃)CF₂O)ₙ—(CF₂O)ₘ—(CF₂)—CF₂CF₃, | Sample-2: side gasket | — | Clear | 0.49 | 0.007 |
| m = 10, n = 10 | of distribution plate | | (FIG. 3-a) | | |
| | (FIG. 3) | | | | |

| | | | hardness | |
|---|---|---|---|---|
| | | | change of | |
| | | | the sample | Change of infrared |
| | | | after | spectrogram before and |
| | | Part No. of the | immersion | after immersion with |
| Perfluoropolyether | | disassembled | (%) (@80° | the perfluoropolyether |
| compound | Source of samples | sample | C., 96 h) | compound |
| CF₃O—(CF(CF₃)CF₂O)ₙ—(CF₂O)ₘ—(CF₂)—CF₂CF₃, | Sample-1: | Part-1 | — | No obvious change, see |
| m = 10, n = 10 | Manufacturer | | | FIG. 1-1b |
| | LUXSHARE-ICT, | Part-2 | — | No obvious change, see |
| | Specification REV | | | FIG. 1-2b |
| | X1 (FIG. 1) | Part-3 | — | No obvious change, see |
| | | | | FIG. 1-3b |
| | | Part-4 | — | No obvious change, see |
| | | | | FIG. 1-4b |
| CF₃O—(CF(CF₃)CF₂O)ₙ—(CF₂O)ₘ—(CF₂)—CF₂CF₃, | Sample-2: PutianTefa | — | — | No obvious change, see |
| m = 10, n = 10 | finished network | | | FIG. 2-b |
| | cable (FIG. 2) | | | |
| CF₃O—(CF(CF₃)CF₂O)ₙ—(CF₂O)ₘ—(CF₂)—CF₂CF₃, | Sample-2: side gasket | — | 0.67 | No obvious change, see |
| m = 10, n = 10 | of distribution plate | | | FIG. 3-b |
| | (FIG. 3) | | | |

In the above test method, as can be seen from the physical comparison chart of the electronic device before and after immersion in the perfluoropolyether liquid cooling agent shown in FIG. 1-1a, FIG. 1-2a, FIG. 1-3a, FIG. 1-4a, FIG. 2-a and FIG. 3-a, the liquid cooling agent still exhibits a clear state, and the electronic device does not suffer from swelling corrosion; in addition, as shown by the test data in Table 2, the volume and weight changes of the electronic device sample before and after immersion are very small. According to the comparison of the infrared spectrogram of the corresponding liquid cooling agent before and after immersion of the electronic device, the overlap ratio of the infrared spectrogram is high, an obvious change is not seen, and the components of the liquid cooling agent are basically unchanged, it demonstrates that the perfluoropolyether liquid cooling agent provided by the present disclosure has excellent material compatibility with the electronic device, and will not cause swelling corrosion of the chip in the device and the relevant wiring, and does not result in the short circuit hazard of the electronic device.

### Compatibility Testing 2:

The computer mainframe was placed in the liquid cooling device, the cooling medium was filled in the liquid cooling device, so that the computer mainframe was completely immersed in the cooling medium, and the computer mainframe was externally connected to a display. The liquid cooling device was connected to a pump, and when the pump operated, the cooling medium was circulated through the pump and carried out heat exchange with a heat exchanger outside the liquid cooling device, as shown in FIG. 4. The cooling medium of the liquid cooling device was the perfluoropolyether liquid cooling agent provided by the present disclosure, under the circumstance that the CPU operated at full load, the computer ran stably for 24 hours, the temperature of the CPU was measured through the CPU-Z program, and the temperature of the cooling medium was displayed by the digital thermometer disposed on the computer mainframe body.

In contrast, the computer mainframe provided heat exchange to the CPU only by using an ordinary fan, which ran for 24 hours under the condition that the CPU operated at full load, the temperature of the CPU was measured through a CPU-Z program.

The test data was shown in Table 3 below, as illustrated by the Table when the perfluoropolyether compound was used as the cooling medium, the CPU cooling effect was higher than that of the heat exchange with an ordinary fan.

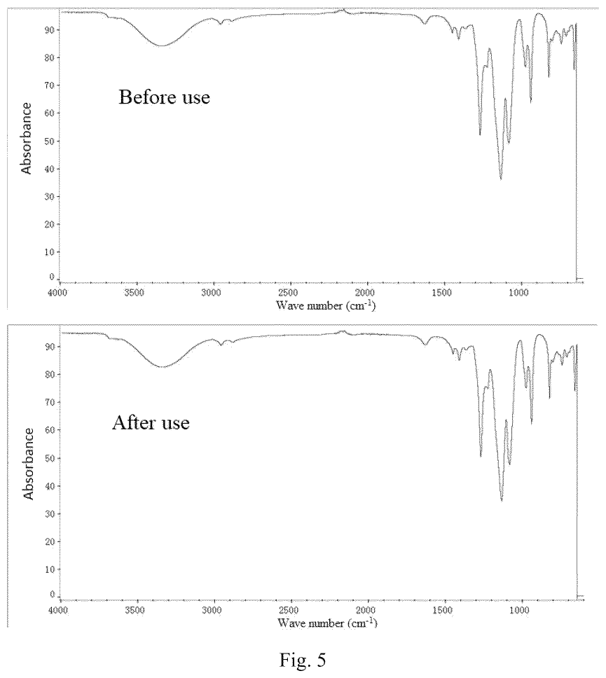

After the perfluoropolyether liquid cooling agent was used as a cooling medium to enable a computer to continuously and stably operate for 1 month, the computer performance was still stable, and the cooling medium did not cause damage to the components such as a main board, a CPU (central processing unit), a GPU (graphic processing unit), the perfluoropolyether liquid cooling agent in the case of the computer was sampled and subjected to the spectrogram analysis to obtain the infrared spectrograms before and after the use of perfluoropolyether liquid cooling agent as shown in FIG. 5, as illustrated by FIG. 5, the components of the perfluoropolyether liquid cooling agent were substantially unchanged, it demonstrated that the liquid cooling agent did not cause swelling corrosion of all accessories of the computer mainframe, the liquid cooling agent exhibited excellent material compatibility.

TABLE 3
CPU temperature test data

| | The | The temperature |
|---|---|---|
| | temperature | of the cooling |
| | of CPU | medium |
| | during heat | during heat |
| Heat exchange modes | exchange/° C. | exchange/° C. |
| Cooling medium: a mixture of | 33.2 | 24.6 |
| CF₃O—(CF(CF₃)CF₂O)₁₀—(CF₂O)₁₀—(CF₂)—CF₂CF₃ and | | |
| HO—CH₂—(CF₂)—(CF(CF₃)CF₂O)₁₀—(CF₂O)₁₀—(CF₂)—CH₂OH | | |
| in a mass ratio of 95:5 | | |
| Fan | 72.5 | — |

Finally, it shall be noted that the aforementioned examples merely serve to explain the technical schemes of the present disclosure, instead of imposing limitations thereto; although the present disclosure has been described in detail with reference to preferred examples thereof, it shall be understood by those skilled in the art that the modification or equivalent replacement may be implemented regarding the technical scheme of the present disclosure without deviating from the essence and scope of the technical scheme of the present disclosure, each shall be contained in the protection scope of claims of the present disclosure.

1. A composition, characterized in that the composition is a perfluoropolyether compound represented by a structural general formula A-(R_{CF}O)ₙ—(CF₂O)ₘ—(CF₂)^{z}—B, or a combination of the perfluoropolyether compound and perfluoropolyether diol represented by a structural general formula HO—CH₂—(CF₂)_{q}—(R_{CF}O)ₙ—(CF₂O)ₘ—(CF₂)CH₂OH;
wherein the groups (R_{CF}O) and (CF₂O) are randomly distributed;
A is a group —F, —CF₃, CF₃CF₂—, CF₃—O—, or CF₃CF₂—O—; B is a group —CF₃ or —CF₂CF₃; R_{CF} is a group —CF₂CF₂—, —CF₂CF₂CF₂—, or —CF(CF₃)CF₂—;
z is an integer between 0 and 2, n and m are both integers greater than 0, the sum n+m is within a range of 2-30, the ratio n/m is within a range of 1-30, q is an integer greater than 0.

2. The composition of claim 1, characterized in that the perfluoropolyether compound is represented by a structural general formula A-(R_{CF}O)ₙ—(CF₂O)ₘ—(CF₂)_{z}—B, wherein A, B, and R_{CF} are the following groups, respectively:
(1) when A is a group —F, —CF₃, CF₃CF₂—, CF₃—O—, or CF₃CF₂—O—, B is a group —CF₃, R_{CF} is a group —CF₂CF₂—;
or (2) when A is a group —F, —CF₃, CF₃CF₂—, CF₃—O—, or CF₃CF₂—O—, B is a group —CF₃, R_{CF} is a group —CF₂CF₂CF₂—;
or (3) when A is a group —F, —CF₃, CF₃CF₂—, CF₃—O—, or CF₃CF₂—O—, B is a group —CF₃; R_{CF} is a group —CF(CF₃)CF₂—;
or (4) when A is a group —F, —CF₃, CF₃CF₂—, CF₃—O—, or CF₃CF₂—O—, B is a group —CF₂CF₃, R_{CF} is a group —CF₂CF₂—;
or (5) when A is a group —F, —CF₃, CF₃CF₂—, CF₃—O—, or CF₃CF₂—O—, B is a group —CF₂CF₃, R_{CF} is a group —CF₂CF₂CF₂—;
or (6) when A is a group —F, —CF₃, CF₃CF₂—, CF₃—O—, or CF₃CF₂—O—, B is a group —CF₂CF₃, R_{CF} is a group —CF(CF₃)CF₂—.

3. The composition of claim 1, characterized in that the perfluoropolyether compound is represented by a structural general formula A-(R_{CF}O)ₙ—(CF₂O)ₘ—(CF₂)_{z}—B, wherein A is a group CF₃—O—; B is a group —CF₂CF₃; R_{CF} is a group —CF(CF₃)CF₂—; z is 1.

4. The composition of claim 1, characterized in that the weight percentage of perfluoropolyether diol represented by a structural general formula HO—CH₂—(CF₂)_{q}—(R_{CF}O)ₙ—(CF₂O)ₘ—(CF₂)_{z}—CH₂OH in the composition is not more than 5%.

5. The composition of claim 1, characterized in that the composition is used as a cooling medium.

6. The composition of claim 5, characterized in that the composition is present in the cooling medium in a content of at least 25% by weight.

7. A liquid cooling agent, characterized in that the liquid cooling agent comprises a perfluoropolyether compound represented by a structural general formula A-(R_{CF}O)ₙ—(CF₂O)ₘ—(CF₂)_{z}—B, or a combination of the perfluoropolyether compound and perfluoropolyether diol represented by a structural general formula HO—CH₂—(CF₂)_{q}—(R_{CF}O)ₙ—(CF₂O)ₘ—(CF₂)_{z}—CH₂OH;
wherein the groups (R_{CF}O) and (CF₂O) are randomly distributed;
A is a group —F, —CF₃, CF₃CF₂—, CF₃—O—, or CF₃CF₂—O—; B is a group —CF₃ or —CF₂CF₃; R_{CF} is a group —CF₂CF₂—, —CF₂CF₂CF₂—, or —CF(CF₃)CF₂—;
z is an integer between 0 and 2, n and m are both integers greater than 0, the sum n+m is within a range of 2-30, the ratio n/m is within a range of 1-30, q is an integer greater than 0.

8. The liquid cooling agent of claim 7, characterized in that the perfluoropolyether compound is represented by a structural general formula A-(R_{CF}O)ₙ—(CF₂O)ₘ—(CF₂)_{z}—B, wherein A, B, and R_{CF} are the following groups, respectively:
(1) when A is a group —F, —CF₃, CF₃CF₂—, CF₃—O—, or CF₃CF₂—O—, B is a group —CF₃, R_{CF} is a group —CF₂CF₂—;
or (2) when A is a group —F, —CF₃, CF₃CF₂—, CF₃—O—, or CF₃CF₂—O—, B is a group —CF₃, R_{CF} is a group —CF₂CF₂CF₂—;
or (3) when A is a group —F, —CF₃, CF₃CF₂—, CF₃—O—, or CF₃CF₂—O—, B is a group —CF₃, R_{CF} is a group —CF(CF₃)CF₂—;
or (4) when A is a group —F, —CF₃, CF₃CF₂—, CF₃—O—, or CF₃CF₂—O—, B is a group —CF₂CF₃, R_{CF} is a group —CF₂CF₂—;
or (5) when A is a group —F, —CF₃, CF₃CF₂—, CF₃—O—, or CF₃CF₂—O—, B is a group —CF₂CF₃, R_{CF} is a group —CF₂CF₂CF₂—;
or (6) when A is a group —F, —CF₃, CF₃CF₂—, CF₃—O—, or CF₃CF₂—O—, B is a group —CF₂CF₃, R_{CF} is a group —CF(CF₃)CF₂—.

9. The liquid cooling agent of claim 7, characterized in that the perfluoropolyether compound is represented by the structural general formula A-(R_{CF}O)ₙ—(CF₂O)ₘ—(CF₂)_{z}—B, wherein A is a group CF₃—O—; B is a group —CF₂CF₃; R_{CF} is a group —CF(CF₃)CF₂—; z is 1.

10. The liquid cooling agent of claim 7, characterized in that the weight percentage of the perfluoropolyether diol is not more than 5% in the combination of the perfluoropolyether compound represented by the structural general formula A-(R_{CF}O)ₙ—(CF₂O)ₘ—(CF₂)_{z}—B and the perfluoropolyether diol represented by the structural general formula HO—CH₂—(CF₂)_{q}—(R_{CF}O)ₙ(CF₂O)ₘ—(CF₂)_{z}—CH₂OH.

11.-18. (canceled)

19. An immersion cooling system, characterized in that the immersion cooling system comprises:
a fully enclosed or incompletely enclosed housing having an inner space;
a heat-generating component disposed in the inner space;
and a cooling medium liquid disposed in the inner space, such that the heat-generating component contacts with the cooling medium liquid;
wherein the cooling medium comprises the composition of claim 1.

20. The immersion cooling system according to claim 19, characterized in that the composition or liquid cooling agent is present in the cooling medium in a content of at least 25% by weight.

21. The immersion cooling system of claim 19, characterized in that the heat-generating component comprises an electronic device.

22. The immersion cooling system of claim 21, characterized in that the electronic device comprises a computer server.

23. The immersion cooling system of claim 21, characterized in that the electronic device comprises a data center.

24. The immersion cooling system of claim 23, characterized in that the data center comprises centrally managed computing resources, equipment of the associated support systems, or a part of the data center, and modular components providing the data center together with other modules.

25. The immersion cooling system of claim 21, characterized in that the electronic device comprises one or more selected from the group consisting of a microprocessor, a semiconductor wafer for manufacturing a semiconductor device, a power control semiconductor, an electrochemical cell, a distribution switching gear, a power transformer, a circuit hoard, a multi-chip module, a packaged or unpackaged semiconductor device, a fuel cell, or a laser.

26. The immersion cooling system of claim 19, characterized in that the heat-generating component is partially or fully immersed in the cooling medium.

27. The immersion cooling system of claim 19, characterized in that the immersion cooling system is a single-phase immersion cooling system.
